(19) United States
(12) Patent Application Publication
(10) Pub. No.: US 2014/0291846 A1
(43) Pub. Date: Oct. 2, 2014

(54) ARRAY SUBSTRATE AND FANOUT LINE STRUCTURE OF THE ARRAY SUBSTRATE

(71) Applicant: SHENZHEN CHINA STAR OPTOELECTRONICS TECHNOLOGY CO., LTD, Shenzhen (CN)

(72) Inventor: Li Chai, Shenzhen (CN)

(73) Assignee: SHENZHEN CHINA STAR OPTOELECTRONICS TECHNOLOGY CO., LTD, Shenzhen (CN)

(21) Appl. No.: 14/113,815

(22) PCT Filed: Jun. 28, 2013
(86) PCT No.: PCT/CN2013/078248

§ 371 Date: Oct. 25, 2013

(30) Foreign Application Priority Data
Mar. 28, 2013 (CN) 201310104856.9

(51) Int. Cl. H01L 23/00

(52) U.S. Cl. CPC H01L 24/20
USPC 257/749

(57) ABSTRACT

A fanout line structure of an array substrate includes a plurality of fanout lines arranged on a fanout area of the array substrate, where the fanout line is used to connect a signal line with a bonding pad. Lengths of different fanout lines are different. At least one fanout line includes a first subsection and a second subsection. An electrical resistivity of material of the second subsection of the fanout line is greater than an electrical resistivity of material of the first subsection of the fanout line. Length of a first fanout line is greater than length of a second fanout line, and length of a second subsection of the second fanout line is greater than length of a second subsection of the first fanout line.

### TECHNICAL FIELD

The present disclosure relates to the field of a liquid crystal display, and more particularly to an array substrate and a fanout line structure of the array substrate.

### BACKGROUND

A liquid crystal (LC) panel is a key component of a liquid crystal display (LCD) device, and a driving circuit cooperating with a backlight unit drives the LC panel to display image.

As shown in FIG. 1, the LC panel includes an array substrate and a color filter substrate. A thin film transistor (TFT) array area 120 is arranged on the LC panel, where signal lines and TFTs are arranged in the TFT array area 120. Bonding pads of a driving circuit board 3 are connected with the signal lines of the array substrate through fanout lines 4, where the fanout lines 4 are arranged on a fanout area.

The bonding pad closely arranged on the driving circuit board 3, but the signal lines are dispersedly arranged in the TFT array area, namely distance between the bonding pad and different signal lines are different, which allows the fanout lines connected between the bonding pad and the signal lines to have different resistance values, thereby affecting display quality of a display device. As shown in FIG. 2, at present, a coiling is arranged in the fanout line allow different lengths and resistance values of fanout lines to obtain even resistance values. As shown in FIG. 3, the fanout line structure includes a first metal layer 410, an insulating layer 420, a second metal layer 430, and a passivation layer 440, where the metal layers are main work layers. A distance between a middle of the bonding pad and corresponding signal lines is shorter than other distances between two ends of the bonding pad and the corresponding signal lines. In order to reduce impedance difference between the fanout lines in the middle of the fanout area and the fanout lines in two ends of the fanout area and improve the display quality of the display device, lengths of the coilings of the fanout lines in the middle of the fanout area increase, which results in an increase of height H of the fanout area (an area is added for accommodating the coiling because length of the coiling of fanout lines increase).

As shown in FIG. 2, using a shortest fanout line and a longest fanout line as an example, where the shortest fanout line is a middle fanout line 200 arranged in the middle of the fanout area, the longest fanout line is a left fanout line 100 arranged at left side of the fanout area, and a right fanout line 300 arranged at right side of the fanout area. Length of the middle fanout line 200 increases through arrangement of the coiling to further increase impedance of the middle fanout line, which reduces impedance difference between the middle fanout line 200 and the longest fanout line (100, 300). The middle fanout line 200 is the shortest fanout line in all fanout lines. Thus, the length of coiling of the middle fanout line 200 is correspondingly longest, thereby increasing height of a middle of the fanout area. When a size of a glass substrate is constant, height of the fanout area increases, and a typesetting of the an array substrate is correspondingly limited, thereby affecting technological development of products. Taking narrow frame design for an example, when the height of the fanout area increases, display area of the LC panel reduces, which means increasing width of the frame of the LCD device.

At present, the length of coiling of the fanout line is reduced by increasing a number of driving integrated circuits, which reduces the height of the fanout area, and obtains the narrow frame, however, cost of production of the LCD device increases, which increases costs.

### SUMMARY provide a display panel and a fanout line structure of an array substrate capable of reducing height of the fanout area and impedance difference between the fanout lines, and further reducing width of a frame of a liquid crystal display (LCD) device.

The purpose of the present disclosure is achieved by the following methods:

A fanout line structure of an array substrate comprises a plurality of fanout lines arranged on a fanout area of the array substrate, where the fanout line is used to connect a signal line with a bonding pad. Lengths of different fanout lines are different. At least one fanout line comprises a first subsection and a second subsection. An electrical resistivity of material of the second subsection of the fanout line is greater than an electrical resistivity of material of the first subsection of the fanout line. Length of a first fanout line is greater than length of a second fanout line, and length of a second subsection of the second fanout line is greater than length of a second subsection of the first fanout line.

Furthermore, the length of the first subsection and the length of the second subsection of different length fanout lines are different, and resistance values of the different length fanout lines are same. Length of the first fanout line is greater than length of the second fanout line, and the length of the second subsection of the second fanout line is greater than the length of the second subsection of the first fanout line, which reduces the impedance difference between two fanout lines having different lengths, even makes impedance differences between two fanout lines having different lengths be about zero.

Furthermore, the first subsection of the fanout line is a metal conducting film arranged on the array substrate, and the second subsection of the fanout line is an indium tin oxide conducting film. The first subsection and the second subsection uses different conducting material, and an electrical resistivity of material of the second subsection of the fanout line is different with an electrical resistivity of material of the first subsection of the fanout line, which reduces impedance difference between the fanout line and other fanout lines through adjusting the lengths of the first subsection and the second subsection of the fanout line.

Furthermore, the first subsection of the fanout line is a double conducting films structure, and comprises a first metal conducting film, an insulating layer, and a second metal conducting film that are successively arranged on the array substrate. The second subsection of the fanout line is an indium tin oxide conducting film. A double metal conducting film allows the fanout lines to steadily work.

Furthermore, in a connection position between the first subsection of the fanout line and the second subsection of the fanout line, the first metal conducting film and the second metal conducting film are configured with an exposed section, where the indium tin oxide conducting film covers the exposed sections, which increases a contact area of the first subsection and the second subsection, thereby improving stability of the electrical connection of the first subsection and the second subsection.

Furthermore, the fanout line comprises a third subsection, and the third subsection is a double conducting films structure. The third subsection comprises the first metal conducting film, the insulating layer, and the second metal conducting film that are successively arranged on the array substrate. Impedance of the fanout line is adjusted through adjusting length of the second subsection of the fanout line. The length of the second subsection of the short fanout line is greater than the length of the second subsection of the long fanout line. According to a typical process, the fanout line is broken in the middle, the second subsection s arranged at the break position, which simplifies the process, and the impedance of the fanout line is adjusted according to the length of the second subsection.

An array substrate comprises a glass substrate configured with a plurality of signal lines, a plurality of fanout lines, and a bonding pad. The fanout lines are arranged on a fanout area of the glass substrate, and are used to connect the signal line with and the bonding pad. Lengths of the plurality of fanout lines are different. At least one fanout line comprises a first subsection and a second subsection, where an electrical resistivity of material of the second subsection of the fanout line is greater than an electrical resistivity of material of the first subsection of the fanout line. Length of a first fanout line is greater than length of a second fanout line, and length of a second subsection of the second fanout line is greater than length of a second subsection of the first fanout line.

Furthermore, the length of the first subsection and the length of the second subsection of different length fanout lines are different, and resistance values of the different length fanout lines are same. Length of the first fanout line is greater than length of the second fanout line, and the length of the second subsection of the second fanout line is greater than the length of the second subsection of the first fanout line, which reduces the impedance difference between two fanout lines having different lengths, even makes impedance differences between two fanout lines having different lengths be about zero

Furthermore, the first subsection of the fanout line is a metal conducting film arranged on the array substrate, and is a double conducting films structure. The first subsection of the fanout line comprises a first metal conducting film, an insulating layer, and a second metal conducting film that are successively arranged on the array substrate. The second subsection of the fanout line is an indium tin oxide conducting film. In a connection position between the first subsection of the fanout line and the second subsection of the fanout line, the first metal conducting film and the second metal conducting film are configured with an exposed section, where the indium tin oxide conducting film covers the exposed sections. The first subsection and the second subsection uses different conducting material, and the electrical resistivity of material of the second subsection of the fanout line is different with the electrical resistivity of material of the first subsection of the fanout line which reduces impedance difference between the fanout line and other fanout lines through adjusting the lengths of the first subsection and the second subsection of the fanout line. double metal conducting film allows the fanout lines to steadily work. The first metal conducting film and the second metal conducting film are configured with the exposed section, where the indium tin oxide conducting film covers the exposed sections, which increases a contact area of the first subsection and the second subsection, thereby improving stability of the electric connection of the first subsection and the second subsection

Furthermore, the fanout line comprises a third subsection, and the third subsection is a double conducting films structure. The third subsection comprises the first metal conducting film, the insulating layer, and the second metal conducting film that are successively arranged on the array substrate. Impedance of the fanout line is adjusted through adjusting length of the second subsection of the fanout line, and the length of the second subsection of the short fanout line is greater than the length of the second subsection of the long fanout line. According to a typical process, the fanout line is broken in the middle, the second subsection is arranged at the break position, which simplifies the process, and the impedance of the fanout line is adjusted according to the length of the second subsection.

In the present disclosure, at least one fanout line of the fanout area of the array substrate comprises the first subsection and the second subsection, where the electrical resistivity of material of the second subsection is greater than the electrical resistivity of material of the first subsection. The lengths of the first subsection and the second subsection of the fanout line are adjusted according to the impedance difference between the fanout line and other fanout lines. Length of the first fanout line is greater than length of the second fanout line, and the length of the second subsection of the second fanout line is adjusted to be greater than the length of the second subsection of the first fanout line through adjusting the lengths of the first subsection and the second subsection of the fanout line, which reduces the impedance difference between the long fanout line and the short fanout lines without coiling design. Thus, when width of the fanout line is constant, a corresponding area of the fanout line accordingly reduces and height of the fanout area accordingly reduces, which increases display area of the LC panel and reduces non-display area of the LC panel, thereby reducing frame of the LCD device, obtaining narrow frame of the LCD device, and reducing production cost of the LCD device (a number of integrated circuits does not increase).

### BRIEF DESCRIPTION OF FIGURES

FIG. 1 is a structural diagram of a typical liquid crystal (LC) panel.

FIG. 2 is a schematic diagram of arranging a fanout line in a fanout area of a typical LC panel.

FIG. 3 is a cross-sectional view along the line D-D in FIG. 2.

FIG. 4 is a schematic diagram of arranging a fanout line of an LC panel of a first example of the present disclosure.

FIG. 5 is a cross-sectional view along the line A-A in FIG. 4.

FIG. 6 is a cross-sectional view along the line B-B in FIG. 4.

FIG. 7 is a cross-sectional view along the line C-C in FIG. 4.

FIG. 8 is a local view of an array substrate of a first example of the present disclosure.

FIG. 9 is a schematic diagram of arranging a fanout line of an LC panel of a second example of the present disclosure.

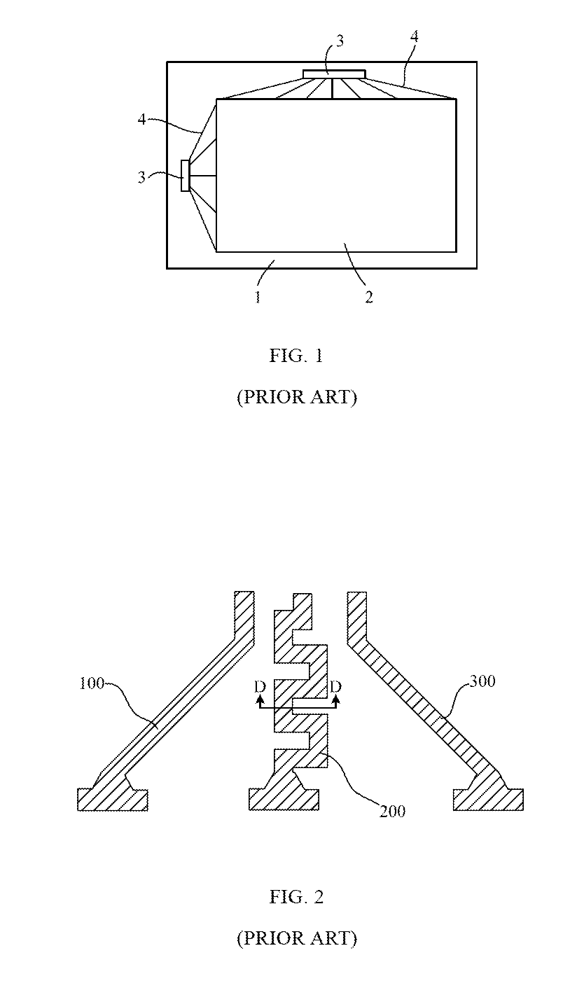

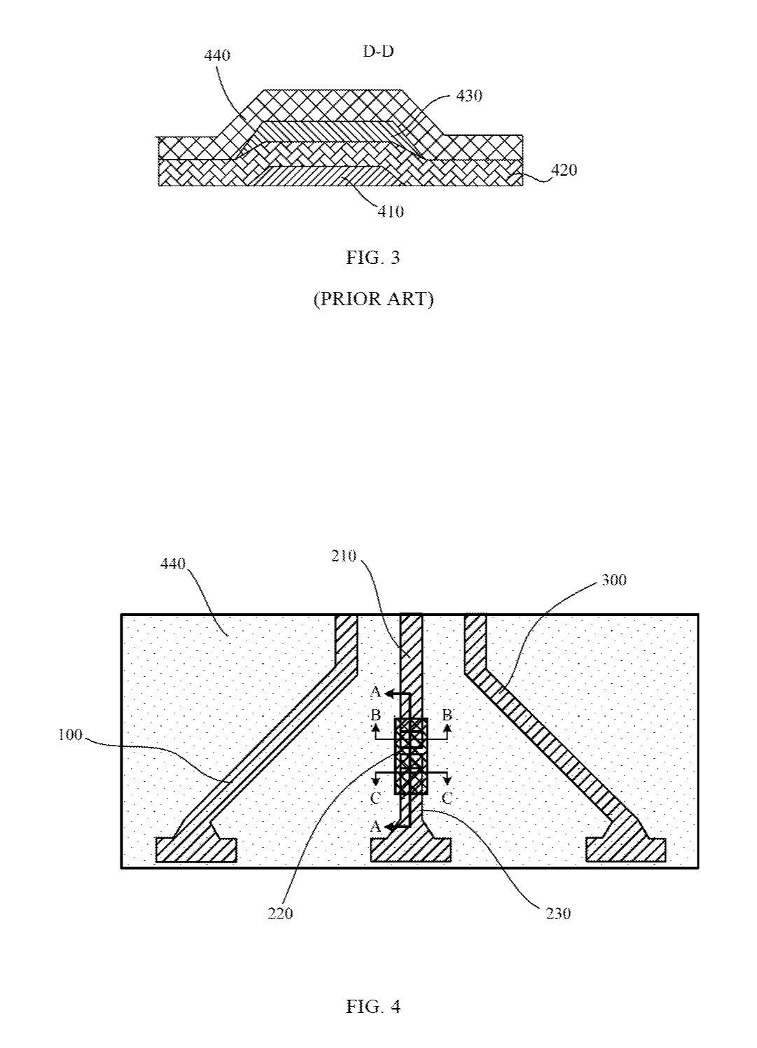

### DETAILED DESCRIPTION

The present disclosure will further be described in detail in accordance with the figures and the exemplary examples.

As shown in FIG. 4, the present disclosure provides a first example of a fanout line structure of an array substrate. A fanout line is used to connect a signal line and a bonding pad. The fanout line structure comprises a plurality of fanout lines arranged on a fanout area of the array substrate, and lengths of the plurality of fanout lines are different. At least one fanout line comprises a first subsection and a second subsection, where an electrical resistivity of material of the second subsection is greater than an electrical resistivity of material of the first subsection. Length of a first fanout line is greater than length of a second fanout line, and length of a second subsection of the second fanout line is greater than length of a second subsection of the first fanout line. The lengths of the first subsection and the second subsection of the fanout line are calculated according to an impedance difference between the fanout line and other fanout lines. A second subsection of a short fanout line is arranged to be longer than a second subsection of a long fanout line through adjusting lengths of a first subsection and the second subsection of the short fanout line, which reduces the impedance difference between the short fanout line and the long fanout line, and even allows the impedance difference between two fanout lines having different lengths to be about zero.

A middlemost fanout line 200, a left-longest fanout line 100, and a right-longest fanout line 300 are used as an example. The middlemost fanout line 200 comprises the first subsection 210, the second subsection 220, and a third subsection 230, where the first subsection 210 of the middlemost fanout line 200 and the third subsection 230 of the middlemost fanout line 200 are connected a driving circuit board with the signal line of the array substrate, respectively. The first subsection 210 of the middlemost fanout line 200 is electrically connected to the third subsection 230 of the middlemost fanout line 200 through the second subsection 220 of the middlemost fanout line 200.

As impedances of the left-longest fanout line 100 and the right-longest fanout line 300 are greatest in all fanout lines, the left-longest fanout line 100 and the right-longest fanout line 300 are not configured with the second subsection. The fanout lines arranged.

between the left-longest fanout line 100 and the right-longest fanout line 300 still need to be configured with the second subsection. As the lengths and impedances of the fanout lines, which are successively arranged along the middlemost fanout line 200 to the left-longest fanout line 100 and the right-longest fanout line 200, successively increase, the length of the second subsection arranged in the fanout lines successively reduce, and a sum of the lengths of the first subsection of the fanout line and the third subsection of the fanout line successively increases, which homogenizes the impedance of different fanout lines, reduces the impedance difference between different fanout lines and even makes the impedance of different fanout lines be same.

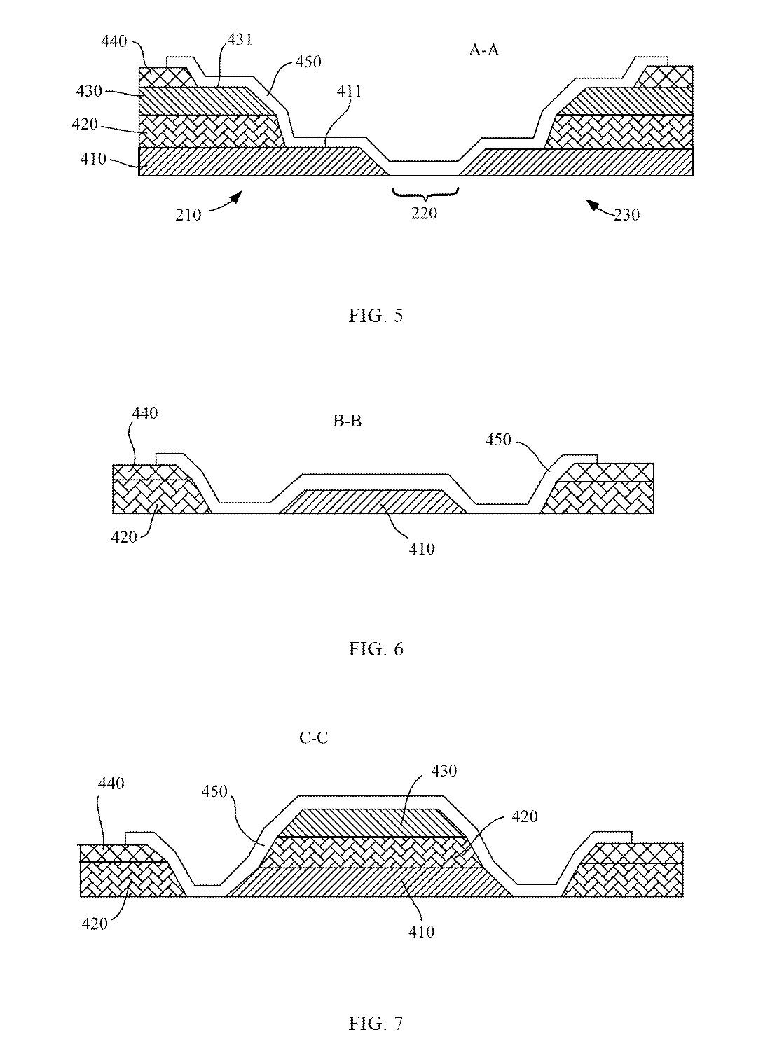

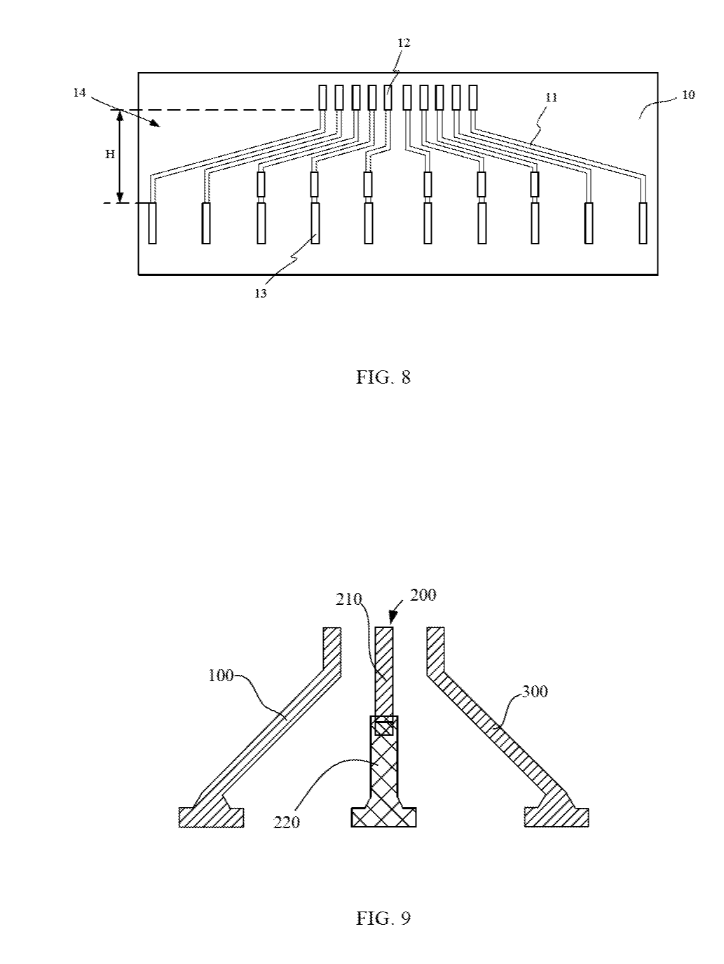

As shown in FIG. 5 and FIG. 7, the first subsection 210 and the third subsection 230 of the middlemost fanout line 200 have a double conducting films structure. The middlemost fanout line 200 comprises a first metal conducting film 410, an insulating layer 420, a second metal conducting film 430, and a passivation layer 440, where a main work layer of the middlemost fanout line 200 is the metal conducting film, namely the first metal conducting film 410 and the second metal conducting film 430. The metal conducting film may be manufactured by using a metal having good conductivity, such as molybdenum Mo, aluminum Al, and copper Cu. The second subsection 220 uses an indium tin oxide (ITO) conducting film where electrical resistivity of the ITO conducting film is greater than the electrical resistivity of the metal conducting film. Thus, the impedance of an entire fanout line can be changed through adjusting the length of the second subsection 220. The second subsection of the short fanout line is longer than the second subsection of the long fanout line. In the example, the left-longest fanout line 100 and the right-longest fanout line 300 are not configured with the second subsection, thus, the lengths of the second subsections of the left-longest fanout line 100 and the right-longest fanout line 300 are regarded as zero, as long as the length of the second subsection of the middlemost fanout line 200 is not zero, the impedance difference between the middlemost fanout line 200 and the left-longest/right-longest fanout line reduces. In order to achieve good effect, the length of the second subsection of the middlemost fanout line 200 is calculated according to actual impedance of the left-longest fanout line 100 and the right-longest fanout line 300, which makes the impedance difference between the middlemost fanout line 200 and the left-longest/right-longest fanout line be minimum or even be about zero.

As shown in FIG. 5 to FIG. 8, in a connection position of the first subsection 210 of the fanout line and the second subsection 220 of the fanout line, the first metal conducting film 410 is configured with an exposed section 411 and the second metal conducting film 430 is configured with an exposed section 431, where the indium tin oxide conducting film 450 covers the exposed sections 411/431. The indium tin oxide conducting film 450 forms the second subsection 220 at break positions of the first subsection 210 and the third subsection 230, which increases a contact area of the first subsection and the third subsection, thereby improving stability of the electrical connection of the first subsection and the third subsection.

In the example, the third subsection and the first subsection have same structure, and the structure of the third subsection comprises the first metal conducting film 410, the insulating layer 420, the second metal conducting film 430, and the passivation layer 440 arranged on the second metal conducting film 430, which are successively arranged on the array substrate. A method of electrically connecting the third subsection 230 to the second subsection 220 is same as a method of electrically connecting the third subsection 230 to the first subsection 210. According to a typical process, the fanout line is broken in the middle, the second subsection is arranged at the break position, which simplifies the process, and the impedance of the fanout line is adjusted according to the length of the second subsection.

The example provides the fanout line structure, as shown in FIG. 8, and the example also provides the array substrate comprising a glass substrate 10, where the glass substrate 10 is configured with a plurality of the signal lines 13, the plurality of the fanout lines 11, and a bonding pad 12. The fanout lines 11 are arranged on the fanout area 14 of the glass substrate 10, and the fanout line structure is the same as the above-mentioned structure.

### Example 2

FIG. 9 shows a second example of the present disclosure. A difference between the second example and the first example is that the middlemost fanout line 200 only comprises the first subsection 210 and the second subsection 220, where the first subsection 210 uses the metal conducting film structure, and the second subsection 220 uses the indium tin oxide conducting film structure. The lengths of the first subsection 210 and the second subsection 220 is calculated according to the impedances of the left-longest fanout line 100 and the right-longest fanout line 300, which reduces the impedance difference between the middlemost fanout line 200 and the left-longest fanout line 100/the right-longest fanout line 300 or even makes the impedance difference be about zero.

The present disclosure is described in detail in accordance with the above contents with the specific exemplary examples. However, this present disclosure is not limited to the specific examples. For example, the fanout line of the present disclosure is not limited to have two or three subsections, under the conception of the present disclosure, the ordinary technical personnel of the technical field of the present disclosure easily uses more subsections. Additionally, the materials of the different subsections are not limited to the metal conducting film and the indium tin oxide conducting film, the ordinary technical personnel of the technical field of the present disclosure easily uses other materials. For the ordinary technical personnel of the technical field of the present disclosure, on the premise of keeping the conception of the present disclosure, the technical personnel can also make simple deductions or replacements, and all of which should be considered to belong to the protection scope of the present disclosure.

We claim:

1. A fanout line structure of an array substrate, comprising:
a plurality of fanout lines arranged on a fanout area of the array substrate;
wherein lengths of different fanout lines are different; the fanout line is used to connect a signal line with a bonding pad;
wherein at least one fanout line comprises a first subsection and a second subsection, an electrical resistivity of material of the second subsection of the fanout line is greater than an electrical resistivity of material of the first subsection of the fanout line; length of a first fanout line is greater than length of a second fanout line, and length of a second subsection of the second fanout line is greater than length of a second subsection of the first fanout line.

2. The fanout line structure of the array substrate of claim 1, wherein the length of the first subsection and the length of the second subsection of different length fanout lines are different, and resistance values of the different length fanout lines are same.

3. The fanout line structure of the array substrate of claim 1, wherein the first subsection of the fanout line is a metal conducting film arranged on the array substrate, and the second subsection of the fanout line is an indium tin oxide conducting film.

4. The fanout line structure of the array substrate of claim 1, wherein the first subsection of the fanout line is a double conducting films structure, and comprises a first metal conducting film, an insulating layer, and a second metal conducting film that are successively arranged on the array substrate; the second subsection of the fanout line is an indium tin oxide conducting film.

5. The fanout lines structure of the array substrate of claim 4, in a connection position between the first subsection of the fanout line and the second subsection of the fanout line, the first metal conducting film and the second metal conducting film are configured with an exposed section; the indium tin oxide conducting film covers the exposed section.

6. The fanout lines structure of the array substrate of claim 4, wherein the fanout line comprises a third subsection, and the third subsection is a double conducting films structure; the third subsection comprises the first metal conducting film, the insulating layer, and the second metal conducting film that are successively arranged on the array substrate; impedance of the fanout line is adjusted through adjusting length of the second subsection Of the fanout line; the length of the second subsection of the short fanout line is greater than the length of the second subsection of the long fanout line.

7. An array substrate, comprising:
a glass substrate configured with a plurality of signal lines, a plurality of fanout lines, and a. bonding pad;
wherein the fanout lines are arranged on a fanout area of the glass substrate, and are used to connect the signal line with and the bonding pad;
wherein lengths of the plurality of fanout lines are different; at least one fanout line comprises a first subsection and a second subsection, an electrical resistivity of material of the second subsection of the fanout line is greater than an electrical resistivity of material of the first subsection of the fanout line; length of a first fanout line is greater than length of a second fanout line, and length of a second subsection of the second fanout line is greater than length of a second subsection of the first fanout line.

8. The array substrate of claim 7, wherein the length of the first subsection and the length of the second subsection of different length fanout lines are different, and resistance values of the different length fanout lines are same.

9. The array substrate of claim 7, wherein the first subsection of the fallout line is a metal conducting film arranged on the array substrate, and is a double conducting films structure; the first subsection of the fanout line comprises a first metal conducting film, an insulating layer, and a second metal conducting film that are successively arranged on the array substrate; the second subsection of the fanout line is an indium tin oxide conducting film; in a connection position between the first subsection of the fanout line and the second subsection of the fanout line, the first metal conducting film and the second metal conducting film are configured with an exposed section; the indium tin oxide conducting film covers the exposed section.

10. The array substrate of claim 9, wherein the fanout line comprises a third subsection, and the third subsection is a double conducting films structure; the third subsection comprises the first metal conducting film, the insulating layer, and the second metal conducting film that are successively arranged on the array substrate; impedance of the fanout line is adjusted through adjusting length of the second subsection of the fanout line; the length of the second subsection of the short fanout hue is greater than the length of the second subsection of the long fanout line.
